(19) United States
(12) Patent Application Publication
(10) Pub. No.: US 2020/0340097 A1
(43) Pub. Date: Oct. 29, 2020

(54) METHOD FOR PRODUCING SPUTTERED SILICON OXIDE ELECTROLYTE

(71) Applicant: The University of Manchester, Manchester (GB)

(72) Inventors: Aimin Song, Manchester (GB); Xiaochen Ma, Manchester (GB)

(21) Appl. No.: 16/482,976

(22) PCT Filed: Feb. 5, 2018
(86) PCT No.: PCT/GB2018/050320

§ 371 Date: Aug. 1, 2019

(30) Foreign Application Priority Data
Feb. 3, 2017 (GB) 1701846.6

(51) Int. Cl. C23C 14/10; C23C 14/34; C23C 14/54; C23C 14/00

(52) U.S. Cl. CPC C23C 14/10; C23C 14/0057; C23C 14/541; C23C 14/3414

(57) ABSTRACT

Embodiments of the present invention provide a sputtered silicon oxide electrolyte and a method for producing the same, wherein one or more of the predetermined pressure of the working gas and the power density per target unit area are controlled such that the sputtered silicon oxide electrolyte has an amorphous structure, a density of between 0.5 to 2.0 g/cm³ and a unit area capacitance of between 0.05 to 15.0 μF/cm² at 10-200 Hz.

### TECHNICAL FIELD

The present invention relates generally to a method for producing sputtered silicon oxide electrolyte and a silicon oxide electrolyte produced thereby.

### BACKGROUND

Thin-film oxide semiconductors offer many advantages over their silicon counterparts and have found uses in many different industries and device applications, such as in the wearable electronics industry and in display drivers, to name only some. The nature of thin-film oxide semiconductors however has meant that their use in transistors in particular requires higher dielectric capacitance materials for fabrication in order to minimise the operating voltage of the transistor itself. Low operating voltages are desirable for applications such as sensors, battery based portable electronics, and other low power electronics. A higher dielectric capacitance in transistors is achieved by thinning the dielectric layer thickness and using materials with especially high dielectric constants. However one or both of these techniques may lead to high current leakage and current bias instability.

It is an object of embodiments of the invention to at least mitigate one or more of the problems of the prior art.

### SUMMARY OF THE INVENTION

Aspects and embodiments of the invention provide a method for producing a sputtered silicon oxide electrolyte and a silicon oxide electrolyte produced thereby.

According to an aspect of the invention, there is provided a method of producing a silicon oxide electrolyte. The method may comprise positioning a silicon-based target material inside a sputtering chamber and a sample at a sample plate of the sputtering chamber. The method may comprise introducing a working gas into the sputtering chamber, ionising the working gas to a power density per target unit area, and sputtering the silicon-based target material onto the sample via bombardment of the ionised working gas at the target material. A predetermined pressure of the working gas may be maintained within the sputtering chamber. One or more of the predetermined pressure of the working gas and the power density per target unit area are controlled such that the sputtered silicon oxide electrolyte has an amorphous structure, a density of between 0.5 to 2.0 g/cm³ and a unit area capacitance of between 0.05 to 15.0 uF/cm² at 10-200 Hz. Advantageously, such properties improve the dielectric performance of the sputtered silicon oxide electrolyte.

In an embodiment of the invention, the silicon-based target material may comprise silicon. In this embodiment, the working gas is ionised via an RF power supply or a DC power supply. Advantageously, a silicon target material allows for a reactive sputtering process to occur.

In an embodiment of the invention, the silicon-based target material may comprise silicon dioxide. In this embodiment, the working gas may be ionised via an RF power supply.

In an embodiment of the invention, the predetermined pressure of the working gas is 0.001 mbar or more. Advantageously, this predetermined pressure may provide desirable electrolyte characteristics.

In an embodiment of the invention, the power density per target unit area is 2.65 W/cm² or below. Advantageously, this power density per target unit area may provide desirable characteristics in the sputtered silicon oxide electrolyte.

In an embodiment of the invention, the sample plate is connected to a cooling system. Advantageously, the cooling system allows the temperature of the sample at the sample plate to be controlled.

In an embodiment of the invention, the temperature of the sample plate is maintained below a deformation temperature of the sample via the cooling system.

Advantageously, this temperature may provide desirable electrolyte characteristics.

In an embodiment of the invention, the sample plate comprises a thermal conductor. Advantageously, this allows for finer control of the sample plate and therefore the sample.

In an embodiment of the invention, the working gas comprises an inert gas. Optionally, the inert gas comprises argon.

In an embodiment of the invention, the working gas further comprises oxygen.

Advantageously, in reactive sputtering processes this allows for the silicon target material atoms to react with the oxygen in the working gas.

In an embodiment of the invention, the sputtering process comprises reactive sputtering.

In an embodiment of the invention, the silicon oxide electrolyte is subjected to a post-fabrication treatment. The post-fabrication treatment may comprise treatment with acid. Advantageously, this may provide desirable electrolyte characteristics, such as higher capacitance properties.

In an aspect of the invention, there is provided a silicon oxide electrolyte produced by the method as described above.

### BRIEF DESCRIPTION OF THE DRAWINGS

Embodiments of the invention will now be described by way of example only, with reference to the accompanying figures, in which:

FIG. 1 shows a method according to an embodiment of the invention; and

FIG. 2 shows an apparatus according to an embodiment of the invention.

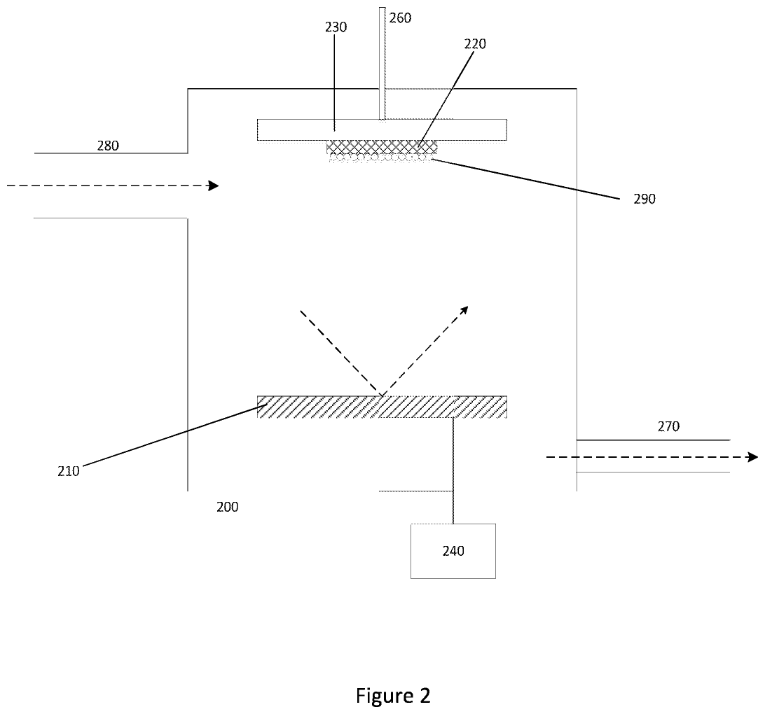

### DETAILED DESCRIPTION

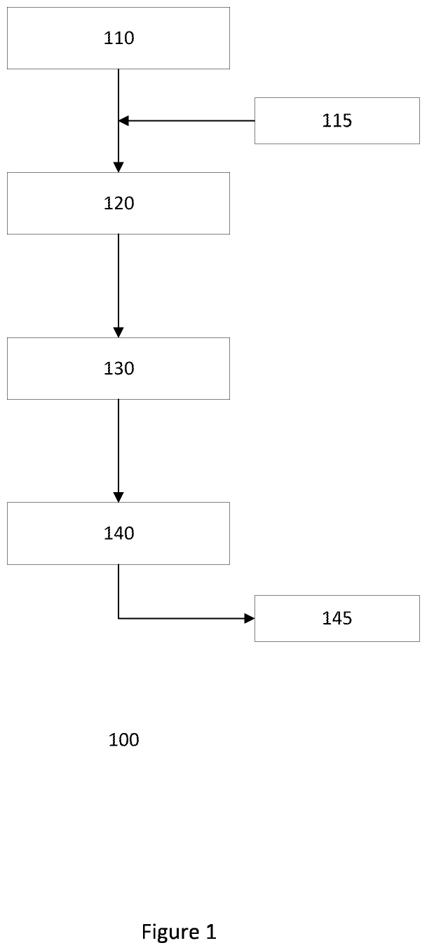

According to an embodiment of the invention, there is provided a method 100 for sputtering a silicon oxide electrolyte 290. The method 100 may be performed via an apparatus as shown in FIG. 1, which comprises a sputtering chamber 200 and a sample plate 230. Arranged within the sputtering chamber 200, in use, is a silicon-based target material 210 and a sample 220. In an embodiment of the invention, the apparatus 200 may further comprise a power supply 240 and a cooling system 260.

In an embodiment of the invention, the silicon-based target material 210 may comprise silicon or silicon dioxide. Applications of silicon oxide electrolytes include use in bio/chemical sensors, as well as gate dielectrics in thin-film oxide transistors other devices due to their high capacitances. Other applications may be envisaged.

In some embodiments, the sputtering chamber 200 may be part of a sputtering system, such as the MiniLab S025M floor-standing manual RF sputter system, although it will be appreciated that other systems may be used.

The method 100 according to some embodiments of the invention comprises a step 110 of positioning the silicon-based target material 210 inside the sputtering chamber 200. In some embodiments, the method comprises positioning the sample 220 at the sample plate 230 of the sputtering chamber 200. In an embodiment of the invention, the silicon-based target material 210 is positioned at a pre-determined distance from one or both of the sample 220 and sample plate 230. The pre-determined distance may be 50 mm or more. In some embodiments the pre-determined distance is 120 mm or more. It has been realised that long sputtering distances encourage the formation of a porous structure in the final electrolyte 290, according to an embodiment of the invention, which is a desirable characteristic, in some applications, for improving low-voltage performance.

In an embodiment of the invention, the sample plate 230 may be connected to the cooling system 260 such that a temperature of the sample 220 may be controlled to provide a deposition temperature. In some embodiments, the sample plate 230 may comprise a thermal conductor. The sample 220 may be cooled by the cooling system 260 via conduction cooling, air cooling, or any other suitable alternative.

In some embodiments, a vacuum may then be formed inside the sputtering chamber 200, as is shown in step 115, in order to minimise the level of contaminants within the sputtering chamber 200. The vacuum may be formed with the use of a pump or similar pumping apparatus 270 coupled to the sputtering chamber 200 which, in use evacuates gas from inside the chamber 200.

Methods according to some embodiments of the invention further comprise the step 120 of introducing a working gas into the sputtering chamber 200. The working gas may be introduced via a working gas valve 280 which operates to control a flow of the working gas. The step 120 may further comprise maintaining a predetermined pressure of the working gas within the sputtering chamber 200 during the sputtering process. The working gas may comprise a chemically inert gas. In embodiments where the silicon-based target material 210 comprises silicon dioxide, the working gas may comprise argon. In other embodiments where the silicon-based target material 210 comprises silicon, the working gas may comprise a mixture of argon and oxygen. The working gas may be maintained at a pressure of 0.001 mbar or more.

In some embodiments, the method further comprises the step 130 of ionising the working gas. In some embodiments, the working gas is ionised via an RF power supply 240. In other embodiments, the working gas is ionised via a power supply 240, which may be a DC power supply 240. The power supply 240 provides, in use, an electric field to accelerate the molecules of the working gas such that they bombard the silicon-based target material 210. In some embodiments, the working gas is ionised to a power density per target unit area ratio. In some embodiments, the power density per target unit area ratio is 2.65 W/cm² or below.

The method may further comprise the step 140 of sputtering the silicon-based target material onto the sample 220. The sputtering may be achieved via bombardment of the ionised working gas at the silicon-based target material 210 to form a silicon oxide electrolyte 290 on the sample 220.

In embodiments where the silicon-based target material 210 comprises silicon dioxide, the process of sputtering is driven by a momentum exchange between the working gas ions and the particles in the silicon-dioxide target material 210 due to collisions. When projected at the silicon-dioxide target material 210, incident working gas ions cause collision cascades in the silicon-dioxide target material 210, resulting in the atoms of the silicon-dioxide target material 210 to be ejected from the target surface and deposited onto the sample 220, thus forming a silicon oxide electrolyte 290.

In embodiments where the silicon-based target material 210 comprises only silicon and the working gas comprises argon and oxygen, reactive sputtering is used as a process for thin-film deposition on the sample 220. In such embodiments, the sputtered atoms of the silicon target material 210 undergo a chemical reaction with the oxygen molecules present in the working gas, before being deposited on the sample 220 and forming a silicon oxide electrolyte 290.

In some embodiments, one or more of the deposition temperature, predetermined pressure of the working gas and the power density per target unit area are controlled such that the sputtered silicon oxide electrolyte 290 has an amorphous structure.

In some embodiments, one or more of the deposition temperature, predetermined pressure of the working gas and the power density per target unit area may be controlled such that the silicon oxide electrolyte has a density of between 0.5 to 2.0 g/cm³.

In some embodiments, one or more of the deposition temperature, predetermined pressure of the working gas and the power density per target unit area may be controlled such that the silicon oxide electrolyte has a unit area capacitance of between 0.05 to 15.0 μF/cm² at 10-200 Hz.

In some embodiments, the method according to an embodiment of the invention further comprises the step 145 of subjecting the silicon oxide electrolyte to a post-fabrication treatment, such as, although not exclusively, acid treatment, in order to enhance the capacitance of the silicon oxide electrolyte.

A sputtered silicon oxide electrolyte 290 is produced according to an embodiment of the invention. The silicon oxide electrolyte may be produced by the method 100 as described with reference to FIG. 1.

Previously, solid-state electrolytes have not been suitable for at least some, or even many, applications due to their operating parameters and complex fabrication requirements. The use of silicon-oxide electrolytes as produced by the method according to an embodiment of the invention as gate dielectrics in InGaZnO (IGZO) thin-film transistors have been tested to provide operating voltages of 1 V, threshold voltages Vₜₕ of 0.06 V, a subthreshold swing SS of 83 mW dec⁻¹, and a high on-off ratio of approximately 10⁵.

It will be appreciated that embodiments of the present invention can be realised in the form of hardware, software or a combination of hardware and software. Any such software may be stored in the form of volatile or non-volatile storage such as, for example, a storage device like a ROM, whether erasable or rewritable or not, or in the form of memory such as, for example, RAM, memory chips, device or integrated circuits or on an optically or magnetically readable medium such as, for example, a CD, DVD, magnetic disk or magnetic tape. It will be appreciated that the storage devices and storage media are embodiments of machine-readable storage that are suitable for storing a program or programs that, when executed, implement embodiments of the present invention. Accordingly, embodiments provide a program comprising code for implementing a system or method as claimed in any preceding claim and a machine readable storage storing such a program. Still further, embodiments of the present invention may be conveyed electronically via any medium such as a communication signal carried over a wired or wireless connection and embodiments suitably encompass the same.

All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings), may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed. The claims should not be construed to cover merely the foregoing embodiments, but also any embodiments which fall within the scope of the claims.

1. A method of producing a silicon oxide electrolyte, comprising:
positioning a silicon-based target material inside a sputtering chamber and a sample at a sample plate of the sputtering chamber;
introducing a working gas into the sputtering chamber, and maintaining a predetermined pressure of the working gas within the sputtering chamber;
ionizing the working gas to a power density per target unit area to obtain an ionized working gas; and
sputtering the silicon-based target material onto the sample via bombardment of the ionized working gas at the target material to form a sputtered silicon oxide electrolyte on the sample;
wherein one or more of the predetermined pressure of the working gas and the power density per target unit area are controlled such that the sputtered silicon oxide electrolyte has an amorphous structure, a density of between 0.5 to 2.0 g/cm³ and a unit area capacitance of between 0.05 to 15.0 uF/cm² at 10-200 Hz.

2. The method of claim 1, wherein the silicon-based target material comprises silicon and the working gas is ionized via an RF power supply.

3. The method of claim 2, wherein the silicon-based target material comprises silicon dioxide and the working gas is ionized via the RF power supply.

4. The method of claim 1, wherein the predetermined pressure of the working gas is 0.001 mbar or more.

5. The method of claim 1, wherein the power density per unit target area is 2.65 W/cm² or below.

6. The method of claim 1, wherein the sample plate is connected to a cooling system.

7. The method of claim 6, wherein temperature of the sample plate is maintained below a deformation temperature of the sample via the cooling system.

8. The method of claim 1, wherein the sample plate comprises a thermal conductor.

9. The method of claim 1, wherein the working gas comprises argon or another inert gas.

10. The method of claim 9, wherein the working gas further comprises oxygen.

11. The method of claim 10, wherein the step of sputtering comprises reactive sputtering.

12. The method of claim 1, wherein the silicon oxide electrolyte is subjected to a post-fabrication treatment comprising treatment with acid or another post-fabrication treatment.

13. A silicon oxide electrolyte produced by the method of claim 1.

14. A method of producing a silicon oxide electrolyte, comprising:
positioning a silicon dioxide target material inside a sputtering chamber and a sample at a sample plate of the sputtering chamber;
introducing a working gas into the sputtering chamber, and maintaining a predetermined pressure of the working gas of 0.001 mbar or more within the sputtering chamber;
ionizing the working gas via a RF power supply to a power density per target unit area, wherein the power density per unit target area is 2.65 W/cm² or below; and
sputtering the silicon dioxide target material onto the sample via bombardment of the ionized working gas at the target material to form a sputtered silicon oxide electrolyte on the sample;
wherein one or more of the predetermined pressure of the working gas and the power density per target unit area are controlled such that the sputtered silicon oxide electrolyte has an amorphous structure, a density of between 0.5 to 2.0 g/cm3 and a unit area capacitance of between 0.05 to 15.0 uF/cm2 at 10-200 Hz;
using the silicon oxide electrolyte as a gate dielectric of a transistor.

15. A method of producing a silicon oxide electrolyte, comprising:
positioning a silicon-based target material inside a sputtering chamber and a sample at a sample plate of the sputtering chamber;
introducing a working gas into the sputtering chamber, and maintaining a predetermined pressure of the working gas within the sputtering chamber;
ionizing the working gas to a power density per target unit area; and
sputtering the silicon-based target material onto the sample via bombardment of the ionized working gas at the target material to form a sputtered silicon oxide electrolyte on the sample;
wherein one or more of the predetermined pressure of the working gas and the power density per target unit area are controlled such that the sputtered silicon oxide electrolyte has an amorphous structure, a density of between 0.5 to 2.0 g/cm³ and a unit area capacitance of between 0.05 to 15.0 uF/cm² at 10-200 Hz;
using the silicon oxide electrolyte as a gate dielectric of a transistor.

16. The method of claim 15, wherein the silicon-based target material comprises silicon and the working gas is ionized via an RF power supply.

17. The method of claim 16, wherein the silicon-based target material comprises silicon dioxide and the working gas is ionized via the RF power supply.

18. The method of claim 15, wherein the predetermined pressure of the working gas is 0.001 mbar or more.

19. The method of claim 15, wherein the power density per unit target area is 2.65 W/cm² or below.

20. The method of claim 15, wherein the sample plate is connected to a cooling system.
